(19) United States
(12) Patent Application Publication
(10) Pub. No.: US 2006/0055016 A1
(43) Pub. Date: Mar. 16, 2006

(54) Chip package assembly produced thereby

(75) Inventor: Kuo-Tung Tiao, Hsin Chu City (TW)

Correspondence Address: TROXELL LAW OFFICE PLLC, SUITE 1404, 5205 LEESBURG PIKE, FALLS CHURCH, VA, 22041, US

(73) Assignee: AIPTEK INTERNATIONAL INC.

(21) Appl. No.: 10/995,487

(22) Filed: Nov. 24, 2004

(30) Foreign Application Priority Data
Sep. 10, 2004 (TW) 93214517

(51) Int. Cl. H01L 23/02; H01L 31/0203; H01L 31/0232

(52) U.S. Cl. 257/680; 257/434; 257/432

(57) ABSTRACT

A chip package assembly is rather than a conventional package assembly and can improve the ability of packaging a photoelectric chip in order to save materials and costs. The chip package assembly includes a transparent substrate, a chip is electrically connected to a circuit layout of the transparent substrate, a joint pad arranged therebetween. Make sure an unoccupied layer is sealed up between the transparent substrate and the chip, so as to form the chip package assembly. After the processes mentioned above are done, the chip package assembly can leave the clean room to run post-processes, such as die sawing, or camera module packaging.

### BACKGROUND OF THE INVENTION

1. Field of the Invention

The present invention relates to a chip package assembly, and particularly relates to a chip package assembly that is rather than conventional package assemblies and can improve the ability of packaging an optical electronic sensor, for example, the optical electronic sensor connects a predetermined region of a circuit layout of a transparent sheet via a conductive material, in order to form an unoccupied layer therebetween. After each chip is packaged, the transparent sheet is sawed into plurality of dices, the dices can be assembled into various camera module.

2. Description of Related Art

As much progress of electronic products does, such as being lightweight, thin, short and small, and being multiple functions, component packages applied for these electronic products develop with high frequency, quantities of I/O ports and microminiaturize. How to increase the production mass of and how to keep the quality of the component packages are the current issues.

With respect to FIG. 1, an optical electronic sensor package assembly 1a processed by the first conventional package method, a chip scale package (CSP) technology, is disclosed. The package assembly 1a includes a substrate 10a, a chip 20a with a micro-lens (μ-lens) array 21a settled on the substrate, a conductive pad 22a arranged on the chip 20a and at the same top surface with the μ-lens array 21a, a terminal wrapping lead 30a arranged from the conductive pad 22a of the chip 20a to a bottom of the substrate 10a, a solder ball array 11a dispensed on the bottom of the substrate 10a for electrically connecting the conductive pad 22a via the terminal wrapping lead 30a, an optical paste 50a coated on the chip 20a, a cover glass 40a stuck to the chip 20a via the optical paste 50a, and a printed circuit board 70a (a flexible board or a generic rigid board) connecting the substrate 10a via the solder ball array 11a by a reflow procedure; thus, the CSP device 1a is provided. During the post-processes, the CSP device 1a further sleeved with a lens holder 60a, a lens 90a and an infrared ray filter 80a in sequence as a camera module. As we know, the refraction index of the conventional cover glass 40a is about 1.6, the refraction index of the optical paste 50a is about 1.5, and the refraction index of the Glens array 21a is about 1.6. However, the optical paste 50a is filled between the chip 20a and the cover glass 40a, according to Snell's Law, the light passes through the cover glass 40 and is transmitted into the μ-lens array 21a via the optical paste 50a, and the CSP device 1a fails to provide good light convergence capacity and the image sensitivity of the camera module is bad. In addition, the CSP device 1a is obviously difficult to manufacture due to the complicated structure per se and the complex steps, the yield rate cannot raise so that the materials and the cost cannot be saved.

Referring to FIG. 2, an optical electronic sensor package assembly 1b processed by the second conventional package method, a chip on board (COB) technology, is disclosed. The package assembly 1b includes printed circuit board 70b (generally a rigid board, or a flexible board also can be used), a chip 20b disposed on the printed circuit board 70b (, the chip 20b has a μ-lens array 21b and a conductive pad 22b arranged at the same surface thereof), a golden wire 30b bonding the conductive pad 22b to the printed circuit board 70b for the electrical connection, a lens holder 60b, a lens 90b and an infrared ray filter 80b gathered together on the printed circuit board 70b in sequence, so as to seal up this COB device 1b as a camera module with directly packaging. The infrared ray filter 80b is arranged inside the lens holder 60b, the lens holder 60b is adhered to the printed circuit board 70b in advance, and the lens 90b is assembled into the lens holder 60b. This camera module can be applied for electronic products hereafter. During the COB processes, if there is any particle or dust fallen on the μ-lens array 21b of the chip 20b, a kind of critical failure mode will damage the image sensing, the fallen particle cannot be removed by any cleaning means, and therefore, the camera module absolutely fails. Thus, for keeping the COB device 1b from the particles and dusts, the whole process will be practiced in a clean room with high criteria, for example, a class 10 clean room in order to increase the yield rate. But such the clean room is so expensive, and the lager size of the clean room for containing all the equipments used in the COB processes costs more than the regular one. Furthermore, in the clean room, the airflow therein should be kept steady and stable, or the disturbed air and the induced particles will affect the yield rate. Nevertheless, the wire bonding procedure causes the air disturbance due to the high speed thereof.

Hence, an improvement over the prior art is required to overcome the disadvantages thereof.

### SUMMARY OF INVENTION

The primary object of the invention is therefore to specify a chip package assembly, in order to save the cost, to increase the yield rate and to provide high image sensitivity.

The secondary object of the invention is therefore to specify a chip package assembly, in order to separate from fallen particles and dusts to avoid damaging the image sensing.

The third object of the invention is therefore to specify a chip package assembly, in order to shorten the time in the clean room for further saving cost.

The fourth object of the invention is therefore to specify a chip package assembly, in order to decrease the frequency of the electrical connection in the package to raise the manufacture efficiency.

The fifth object of the invention is therefore to specify a chip package assembly, in order to omitting the reflowing process for increasing the manufacture efficiency.

According to the invention, these objects are achieved by a chip package assembly includes a transparent substrate, a chip arranged beneath the transparent substrate, a joint pad, a sealing paste coated around the joint pad, and a lens module arranged over the transparent substrate. The transparent substrate has a first surface and a circuit layout planted on a predetermined region of the first surface for electrical connection. The joint pad connects with the circuit layout of the transparent substrate and the chip. The sealing paste connects the joint pad, the chip and the transparent substrate simultaneously, so as to form an unoccupied layer sealed up between the chip and the transparent substrate.

According to the invention, these objects are achieved by a chip package assembly includes a transparent substrate having a first surface and a circuit layout planted on a predetermined region of the first surface for electrical connection, a chip arranged beneath the transparent substrate, a joint pad connecting with the circuit layout of the transparent substrate and the chip, and a sealing paste coated around the joint pad; wherein the sealing paste connects the joint pad, the chip and the transparent substrate simultaneously.

According to the invention, these objects are achieved by a chip package assembly includes a transparent substrate having a first surface and a circuit layout planted on a predetermined region of the first surface for electrical connection, a chip arranged beneath the transparent substrate, and a joint pad connecting with the circuit layout of the transparent substrate and the chip.

To provide a further understanding of the invention, the following detailed description illustrates embodiments and examples of the invention. Examples of the more important features of the invention thus have been summarized rather broadly in order that the detailed description thereof that follows may be better understood, and in order that the contributions to the art may be appreciated. There are, of course, additional features of the invention that will be described hereinafter and which will form the subject of the claims appended hereto.

### BRIEF DESCRIPTION OF THE DRAWINGS

These and other features, aspects, and advantages of the present invention will become better understood with regard to the following description, appended claims, and accompanying drawings, where:

FIG. 1 is a cross-sectional profile of the first conventional package assembly;

FIG. 2 is a cross-sectional profile of the second conventional package assembly FIG. 3A is a cross-sectional profile of a chip package assembly dicing according to the present invention;

FIG. 3B is a bottom view of the chip package assembly according to a first embodiment of the present invention;

FIG. 3C is an enlarged view of the chip package assembly according to the present invention;

FIG. 3D is a bottom view of the chip package assembly according to a second embodiment of the present invention;

FIG. 3E is a perspective view of the chip package assembly according to a first embodiment of the present invention; and

FIG. 3F is a perspective view of the chip package assembly according to a second embodiment of the present invention.

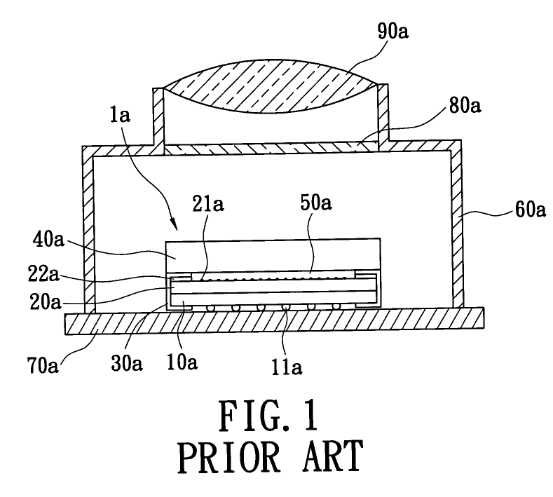

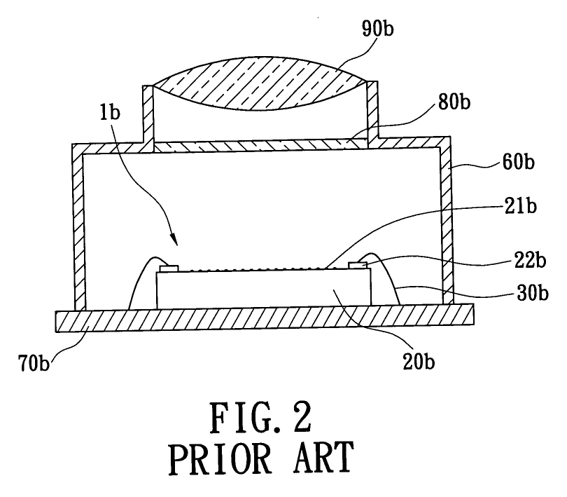

### DETAILED DESCRIPTION OF THE EMBODIMENTS

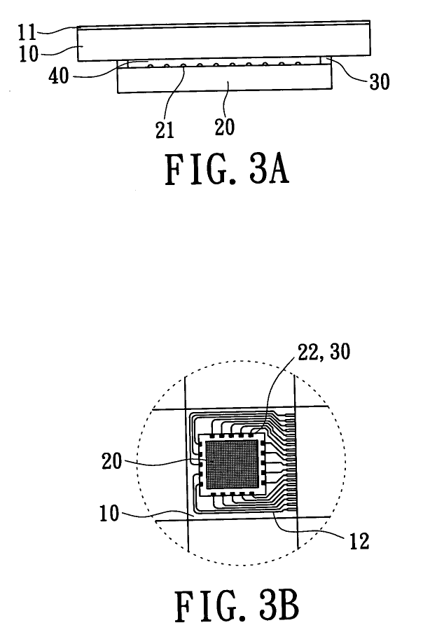

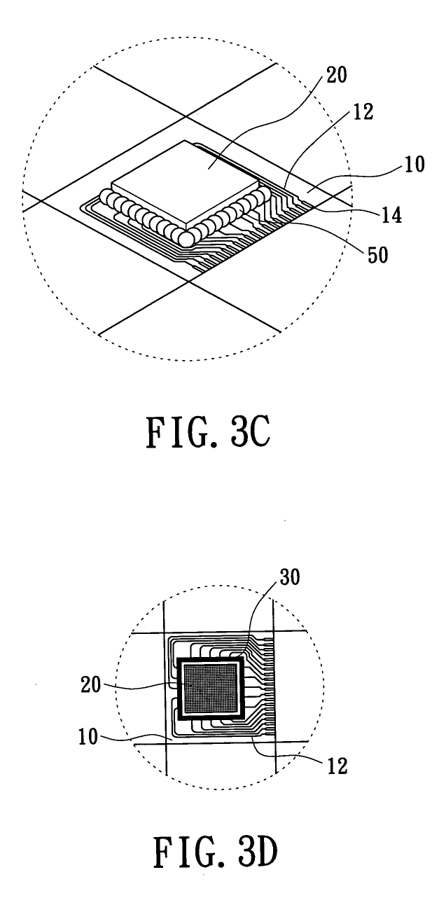

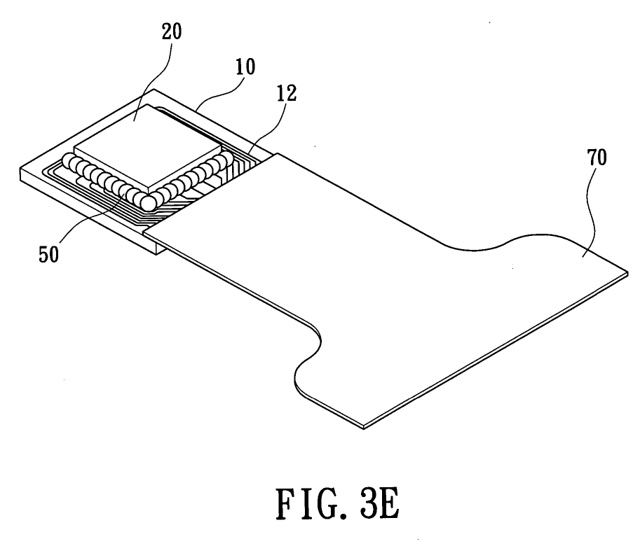

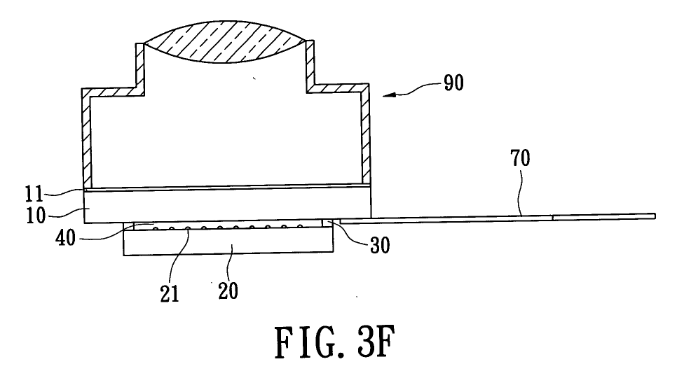

With respect to FIGS. 3A to 3F, a chip package assembly is disclosed. The chip package assembly (in FIG. 3A) includes a transparent substrate 10 having a first surface and a circuit layout 12 planted on a predetermined region of the first surface for electrical connection, a chip 20 arranged beneath the transparent substrate 10, and a joint pad 30 connecting the circuit layout 12 of the transparent substrate 10 and the chip 20. The joint pad 30 illustrated in FIG. 3B according to an embodiment is arranged in a discontinuous manner, and the chip package assembly further includes a sealing paste 50 coated around the joint pad 30 for connecting the joint pad 30, the chip 20 and the transparent substrate 10 simultaneously, so as to form an unoccupied layer 40 sealed up and isolated between the chip 20 and the transparent substrate 10 for high image sensitivity. The joint pad 30 illustrated in FIG. 3D according to another embodiment is circled and arranged in a continuous manner, in order to form an unoccupied layer 40 sealed up between the chip 20 and the transparent substrate 10 without a sealing paste 50. Thus, the unoccupied layer 40 sealed up and formed between the chip 20 and the transparent substrate 10 really can prevent particles and dusts from damaging micro lens disposed therein, or can isolate other relevant factors, such as moisture or volatile solvents, to prolong the service life. Besides, since the transparent substrate 10 provided with the circuit layout 12 and the chip 20 connects the circuit layout 12 via the joint pad 30, the transparent substrate 10 functions with a circuit board and a cover glass (for prevent from particles and dusts) at the same time. After the unoccupied layer 40 is sealed up, the chip package assembly can leave the clean room to run the conventional post-processes, such as die sawing or camera module packaging with a lens module 90 arranged over the transparent substrate 10 (FIG. 3F). The chip package assembly is rather than a conventional package assembly and can improve the ability of packaging a photoelectric chip, so that the camera module size can be shrank, the processes can be simplified, the materials and the labor can be saved, and the manufacture efficiency can be improved at the same time. Obviously, the chip package assembly according to the present invention is with real low cost and huge effects for applying in the optical electronic sensor packaging plants.

Referring to FIG. 3A, the transparent substrate 10 is made of optical glass (or can be made of quartz, but more expensive). In the preferred embodiment, the transparent substrate 10 has a second surface opposite to the first surface and an electromagnetic wave reflection layer arranged on the second surface, the electromagnetic wave reflection layer reflects a predetermined wave spectrum of the electromagnetic wave, wherein the electromagnetic wave reflection layer is an infrared ray filtering film 11 in order to take place of the infrared ray filter 80a or 80b in the conventional assemblies. The transparent substrate 10 further includes a protection circuit electrically connecting the layout circuit 12, and the protection circuit includes an overload protection member, a load regulator, a current regulator, a noise removal, or an emergency shutdown device (ESD) for keeping the signal clear and steady. The transparent substrate 10 further includes a golden finger 14 (in FIG. 3C) arranged on an edge thereof and electrically connecting the layout circuit 12, The chip 20 is a kind of optical electronic sensors, and has a micro-lens array 21 disposed on the surface thereof to face the first surface of the transparent substrate 10, and an image reveal array (not shown) arranged under and corresponding to the micro-lens array 21. The chip 20 can be an optical sensor with a pixel array, such as a CMOS (Complementary Metal-Oxide Semi conductor), a CCD (Charge Coupled Device), or a CIS (Contact Image Sensor), wherein the image reveal array is the pixel array. In addition, a plurality of LEDs (Light Emission Diode) arranged on a transparent sheet in advance, and the sheet with the LEDs is sawed into proper scaled-and-sized individual dices to apply to a commercial board for showing messages or words. The LEDs with the transparent substrate 10 can be sputtered with a reflection/interference film thereon for enhancing the color contrast of the LEDs. Thus, the chip 20 can be composed of the LEDs corresponding to the micro-lens array one on one. With respect to FIG. 3B, the chip 20 includes a plurality of conjunctions along a circumference thereof for overlapping and connecting the discontinuous joint pad 30 in order to electrically connecting the layout circuit 12 of the transparent substrate 10.

The joint pad 30 can be made on the chip 20 or the layout circuit 12 of the transparent substrate 10 in advance. If the joint pad 30 is arranged in a discontinuous manner, the joint pad 30 can be made of a conductive material directly, such as a golden pump, or an anisotropic conductive film and paste (ADF). If the joint pad 30 is made from the golden pump, the golden bump is made on the chip 20 or on the circuit layout 12 of the transparent substrate 10 in advance, and the chip 20 and the circuit layout 12 of the transparent substrate 10 will be welded to each other by the golden bump. If the joint pad 30 is made from the ADF, the ADF can be made on the chip 20 or on the circuit layout 12 of the transparent substrate 10 in advance, as same as the golden bump, thus the chip 20 and the circuit layout 12 of the transparent substrate 10 will be stuck to each other. Any way, the chip 20 connects the circuit layout 12 of the transparent substrate 10 electrically via the joint pad 30. In regard to FIG. 3C, another embodiment of the joint pad 30 is disclosed. The joint pad 30 is circled in a continuous manner in order to form the unoccupied layer 40 between the chip 20 and the transparent substrate 10 directly. For considering problems of short or other electrical functions, the joint pad 30 is made of a conductive material and an insulative material alternately. The conductive material is used to electrically connect the conjunctions 22 of the chip 20, and the insulation material is used to continue the conductive material. So the conductive material can be the golden bump or the ADF. The unoccupied layer 40 is formed by pumping into vacuum, being full of air naturally, or pouring an inert gas between the chip 20 and the transparent substrate 10 for isolation from moisture, other particles or others. In FIG. 3D, the unoccupied layer 40 is formed directly by the joint pad 30. FIG. 3B illustrates a sealing paste 50 provided to guarantee the absolute isolation. If the transparent substrate 10 is made of a glass, and the refraction index of the glass is about 1.6, the refraction index of the micro lens is about 1.6, and the refraction index of vacuum is about 1. According to Snell's Law, the light passes through the transparent substrate 10 and is transmitted into the g-lens array 21 via the vacuum, and the chip package assembly provides good light convergence capacity and the image sensitivity of the camera module is excellent.

FIG. 3E illustrates the chip assembly further including a printed circuit board 70 (, which can be a flexible board) electrically connecting the golden finger 14. The transparent substrate 10 can connect the board 70 by hot bar, and apply for an electronic product via the board 70.

In regard to FIG. 3F, the lens module 90 includes a lens, and a lens holder received the lens and assembled to the transparent substrate 10 (by screwing or other methods).

Because the chip 20, the transparent substrate10 and the joint pad 30 are assembled together with a thin size, the chip package assembly is thin enough to shrink the height of the camera module for size reduction.

The transparent substrate 10 functions not also as the printed circuit board 70a or 70b in the conventional assemblies, but also as the cover glass 40a or 40b for preventing from particles and dusts. The fallen particles onto the transparent substrate 10 can be removed directly by alcohol or IPA (Isopropyl alcohol), so as to decrease the critical failure modes that damage the image sensing. The chip package assembly according to the present invention can be practiced with simple steps to avoid the soldering process or the wire bonding processes in the CSP or COB assemblies, particularly the omission of the soldering process can diminish the risks of the product damages. In addition, too many electrical connections (the chip 20a electrically connects the conductive pad 22a and the solder ball array 11a via the terminal wrapping lead 30a, and the chip 20a electrically connects the printed circuit board 70a via the solder ball array 11a.) in the CSP assembly will prolong the produce time. In the present invention, this problem can be solved, too. Furthermore, the chip package assembly is sealed up for isolation and can leave the clean room early. The processes and the equipments in the clean room both will be reduced to save money.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A chip package assembly comprising:
a transparent substrate having a first surface and a circuit layout planted on a predetermined region of the first surface for electrical connection;
a chip arranged beneath the transparent substrate;
a joint pad connecting with the circuit layout of the transparent substrate and the chip;
a sealing paste coated around the joint pad; and
a lens module arranged over the transparent substrate;
wherein the sealing paste connects the joint pad, the chip and the transparent substrate simultaneously, so as to form an unoccupied layer sealed up between the chip and the transparent substrate.

2. The chip package assembly as claimed in claim 1, wherein the unoccupied layer is a layer of vacuum, air or inner gas.

3. The chip package assembly as claimed in claim 1, wherein the transparent substrate is made of optical glass or quartz.

4. The chip package assembly as claimed in claim 1, wherein the transparent substrate further has a second surface opposite to the first surface and an electromagnetic wave reflection layer arranged on the second surface, the electromagnetic wave reflection layer reflects a predetermined wave spectrum of the electromagnetic wave.

5. The chip package assembly as claimed in claim 4, wherein the electromagnetic wave reflection layer is an infrared ray filtering film.

6. The chip package assembly as claimed in claim 1, wherein the joint pad is made of a conductive material

7. The chip package assembly as claimed in claim 6, wherein the joint pad is made on the chip or on the circuit layout of the transparent substrate in advance.

8. The chip package assembly as claimed in claim 6, wherein the joint pad is a golden pump, or an anisotropic conductive film and paste (ADF).

9. The chip package assembly as claimed in claim 1, wherein the chip has a micro-lens array disposed on a surface thereof to face the first surface of the transparent substrate.

10. The chip package assembly as claimed in claim 9, wherein the chip is an optical sensor with a pixel array that corresponds to the micro-lens array; or the chip is composed of a plurality of LEDs (Light Emission Diode) corresponding to the micro-lens array one on one.

11. The chip package assembly as claimed in claim 1, wherein the transparent substrate further includes a protection circuit electrically connecting the layout circuit.

12. The chip package assembly as claimed in claim 11, wherein the protection circuit includes an overload protection member, a load regulator, a current regulator, a noise removal, or an emergency shutdown device (ESD).

13. The chip package assembly as claimed in claim 1, wherein the transparent substrate further includes a golden finger electrically connecting the layout circuit.

14. The chip package assembly as claimed in claim 13, further including a printed circuit board electrically connecting the golden finger.

15. The chip package assembly as claimed in claim 1, wherein the lens module includes a lens, and a lens holder received the lens and assembled to the transparent substrate.

16. A chip package assembly comprising:
a transparent substrate having a first surface and a circuit layout planted on a predetermined region of the first surface for electrical connection;
a chip arranged beneath the transparent substrate;
a joint pad connecting with the circuit layout of the transparent substrate and the chip; and
a sealing paste coated around the joint pad; wherein the sealing paste connects the joint pad, the chip and the transparent substrate simultaneously.

17. The chip package assembly as claimed in claim 16, wherein the joint pad is arranged in a discontinuous manner, and is sealed up via the sealing paste, so as to form an unoccupied layer between the chip and the transparent substrate.

18. The chip package assembly as claimed in claim 17, wherein the unoccupied layer is a layer of vacuum, air or inner gas.

19. The chip package assembly as claimed in claim 16, wherein the transparent substrate is made of optical glass or quartz.

20. The chip package assembly as claimed in claim 16, wherein the transparent substrate further has a second surface opposite to the first surface and an electromagnetic wave reflection layer arranged on the second surface, the electromagnetic wave reflection layer reflects a predetermined wave spectrum of the electromagnetic wave.

21. The chip package assembly as claimed in claim 20, wherein the electromagnetic wave reflection layer is an infrared ray filtering film.

22. The chip package assembly as claimed in claim 16, wherein the joint pad is made of a conductive material

23. The chip package assembly as claimed in claim 22, wherein the joint pad is made on the chip or on the circuit layout of the transparent substrate in advance.

24. The chip package assembly as claimed in claim 22, wherein the joint pad is a golden pump, or an anisotropic conductive film and paste (ADF).

25. The chip package assembly as claimed in claim 16, wherein the chip has a micro-lens array disposed on a surface thereof to face the first surface of the transparent substrate.

26. The chip package assembly as claimed in claim 25, wherein the chip is an optical sensor with a pixel array that corresponds to the micro-lens array; or the chip is composed of a plurality of LEDs (Light Emission Diode) corresponding to the micro-lens array one on one.

27. The chip package assembly as claimed in claim 16, wherein the transparent substrate further includes a protection circuit electrically connecting the layout circuit.

28. The chip package assembly as claimed in claim 27, wherein the protection circuit includes an overload protection member, a load regulator, a current regulator, a noise removal, or an emergency shutdown device (ESD).

29. The chip package assembly as claimed in claim 16, wherein the transparent substrate further includes a golden finger electrically connecting the layout circuit.

30. The chip package assembly as claimed in claim 29, further including a printed circuit board electrically connecting the golden finger.

31. The chip package assembly as claimed in claim 16, further including a lens module arranged over the transparent substrate.

32. The chip package assembly as claimed in claim 31, wherein the lens module includes a lens, and a lens holder received the lens and assembled to the transparent substrate.

33. A chip package assembly comprising:
a transparent substrate having a first surface and a circuit layout planted on a predetermined region of the first surface for electrical connection;
a chip arranged beneath the transparent substrate; and
a joint pad connecting with the circuit layout of the transparent substrate and the chip.

34. The chip package assembly as claimed in claim 33, wherein the joint pad is circled around the chip in a continuous manner in order to form an unoccupied layer sealed up between the chip and the transparent substrate.

35. The chip package assembly as claimed in claim 34, wherein the unoccupied layer is a layer of vacuum, air or inner gas.

36. The chip package assembly as claimed in claim 16, wherein the transparent substrate is made of optical glass or quartz.

37. The chip package assembly as claimed in claim 33, wherein the transparent substrate further has a second surface opposite to the first surface and an electromagnetic wave reflection layer arranged on the second surface, the electromagnetic wave reflection layer reflects a predetermined wave spectrum of the electromagnetic wave.

38. The chip package assembly as claimed in claim 37, wherein the electromagnetic wave reflection layer is an infrared ray filtering film.

39. The chip package assembly as claimed in claim 33, wherein the joint pad is made of a conductive material and an insulative material in an alternate manner.

40. The chip package assembly as claimed in claim 39, wherein the joint pad is made on the chip or on the circuit layout of the transparent substrate in advance.

41. The chip package assembly as claimed in claim 39, wherein the conductive material is a golden pump, or an anisotropic conductive film and paste (ADF).

42. The chip package assembly as claimed in claim 33, wherein the chip has a micro-lens array disposed on a surface thereof to face the first surface of the transparent substrate.

43. The chip package assembly as claimed in claim 42, wherein the chip is an optical sensor with a pixel array that corresponds to the micro-lens array; or the chip is composed of a plurality of LEDs (Light Emission Diode) corresponding to the micro-lens array one on one.

44. The chip package assembly as claimed in claim 33, wherein the transparent substrate further includes a protection circuit electrically connecting the layout circuit.

45. The chip package assembly as claimed in claim 44, wherein the protection circuit includes an overload protection member, a load regulator, a current regulator, a noise removal, or an emergency shutdown device (ESD).

46. The chip package assembly as claimed in claim 33, wherein the transparent substrate further includes a golden finger electrically connecting the layout circuit.

47. The chip package assembly as claimed in claim 46, further including a printed circuit board electrically connecting the golden finger.

48. The chip package assembly as claimed in claim 33, further including a lens module arranged over the transparent substrate.

49. The chip package assembly as claimed in claim 48, wherein the lens module includes a lens, and a lens holder received the lens and assembled to the transparent substrate.
